(19) United States
(12) Patent Application Publication
(10) Pub. No.: US 2022/0161661 A1
(43) Pub. Date: May 26, 2022

(54) METHOD FOR THE RAPID INITIALIZATION OF AN ELECTRICAL ENERGY STORAGE SYSTEM

(71) Applicant: Robert Bosch GmbH, Stuttgart (DE)

(72) Inventor: Dietrich Wentland, Stuttgart (DE)

(21) Appl. No.: 17/601,224

(22) PCT Filed: Mar. 25, 2020
(86) PCT No.: PCT/EP2020/058267

§ 371 Date: Oct. 4, 2021

(30) Foreign Application Priority Data
Apr. 2, 2019 (DE) 10 2019 204 637.1

(51) Int. Cl. B60L 3/00; B60L 58/10; G01R 31/367; G01R 31/382; H01M 10/48; H01M 10/42; H02J 7/00

(52) U.S. Cl. CPC B60L 3/0046; B60L 58/10; G01R 31/367; G01R 31/382; H01M 10/486; H01M 10/48; H01M 2010/4271; H02J 7/0047; B60L 2240/545; B60L 2240/547; B60L 2240/549; H01M 2220/20; H01M 10/425

(57) ABSTRACT

The invention relates to a method for the rapid initialization of an electrical energy storage system comprising the following steps: a) miming at least one predefined diagnosis of the electrical energy storage system to achieve at least one predefined first diagnosis coverage; b) determining an achieved second diagnosis coverage on the basis of the at least one diagnosis run in step a); c) saving the achieved second diagnosis coverage in a first data memory; d) running no more than a portion of the at least one predefined diagnosis of step a) to achieve at least one predefined third diagnosis coverage; e) determining an achieved fourth diagnosis coverage on the basis of the portion of the at least one predefined diagnosis run in step d); f) storing the achieved fourth diagnosis coverage in a second data memory. The invention further relates to a corresponding device and a corresponding electrical energy storage system.

### BACKGROUND OF THE INVENTION

The present invention is based on a method for the rapid initialization of an electrical energy storage system, a corresponding apparatus and a corresponding electrical energy storage unit.

As electrification, in particular of motor vehicles, increases, electrical energy stores are becoming ever increasingly important. In this case, there are different levels of electrification. For example, there are electrically driven vehicles with and without an internal combustion engine and vehicles in which an electric motor takes over the driving of the vehicle only at times or supports the internal combustion engine. These different forms of electrification typically have different voltage levels and different configurations of the electrical energy storage units used.

In order to guarantee the reliability of an applicable electrical energy storage system, extensive diagnoses are performed on the electrical energy storage system which, for example, concern temperature level, voltage level and current level or the associated measurement chains and/or the measurement values acquired thereby. As a result, when a vehicle is switched on or before electrical energy is retrieved from the electrical energy storage system, it is established whether said electrical energy storage system is guaranteed to be reliable and available.

Performing these diagnoses requires a certain amount of time, during which it is not possible to retrieve electrical energy or store electrical energy in the electrical energy storage system as appropriate. The electrical energy storage system is therefore not available, and an applicable vehicle cannot be operated, during this time.

### SUMMARY OF THE INVENTION

A method for the rapid initialization of an electrical energy storage system is disclosed.

In this case, at least one predefined diagnosis of the electrical energy storage system is performed in a first step to obtain a predefined first degree of diagnostic coverage. By way of example, all diagnoses that are prescribed can be performed to therefore obtain a degree of diagnostic coverage of 100%. The degree of diagnostic coverage here indicates, for example, how often applicable diagnoses are performed. If diagnoses are not carried out over a relatively long period, for example, the degree of diagnostic coverage worsens.

By way of example, a diagnosis can consist of a check being performed to determine whether a circuit present in the electrical energy storage system is still functioning correctly, for example when the circuit is used for voltage measurement. For this purpose, transistors in this circuit are usually switched accordingly and acquired voltages are measured in the closed and open state of the transistors. These voltages are checked, wherein, depending on the circuit, they have to be equal to, smaller than or larger than a predefined value or have to correspond to the predefined value.

Furthermore, an obtained second degree of diagnostic coverage is determined in a second step on the basis of the at least one diagnosis performed in the step mentioned above, and is stored in a first data memory in a third step so as to be able to be read, for example, by a diagnostic unit, for example an OBD diagnostic device. In this case, the first data memory can be present in a battery management control device, for example.

Subsequently, for example depending on a condition, for example switching the ignition off and on via terminal 15, no more than a portion of the at least one predefined diagnosis from the step mentioned above is performed in a fourth step to obtain a predefined third degree of diagnostic coverage, for example 80%.

Furthermore, an obtained fourth degree of diagnostic coverage is determined in a fifth step on the basis of the portion of the at least one predefined diagnosis that was performed in the step mentioned above, and the obtained fourth degree of diagnostic coverage is stored in a second data memory in a sixth step so as to be able to be read by a diagnostic device, for example. In this case, the stored second degree of diagnostic coverage can be overwritten by storing the fourth degree of diagnostic coverage if the first data memory and the second data memory are the same. This procedure is advantageous since it reduces the time for a further diagnosis of the electrical energy storage system and simultaneously ensures the reliability of the latter. At the same time, it is possible to tell how high the degree of diagnostic coverage is and whether it complies with any possible legal requirements. More rapid retrieval of electrical energy is possible in the event of a switching-on process with a subsequent switching-off process and a further switching-on process of the electrical energy storage system.

The electrical energy storage system expediently comprises a plurality of electrical energy storage units. This is advantageous in order to be able to provide a high electrical power. An electrical energy storage unit can in particular be understood to mean an electrochemical battery cell and/or a battery module having at least one electrochemical battery cell and/or a battery pack having at least one battery module. By way of example, the electrical energy storage unit can be a lithium-based battery cell or a lithium-based battery module or a lithium-based battery pack. In particular, the electrical energy storage unit can be a lithium-ion battery cell or a lithium-ion battery module or a lithium-ion battery pack. Furthermore, the battery cell can be of the lithium-polymer accumulator, nickel-metal hydride accumulator, lead-acid accumulator, lithium-air accumulator or lithium-sulfur accumulator type, or quite generally an accumulator of any electrochemical composition. A capacitor is also possible as the electrical energy storage unit.

The step of performing no more than a portion of the at least one predefined diagnosis is expediently started within a predefined period of time from the execution or end of the step of performing the at least one predefined diagnosis. This period of time can be, for example, 60 s, in particular 10 s. This is advantageous since it makes use of the fact that the electrical energy storage system has probably not changed significantly in the predefined period of time and therefore some of the diagnoses can be dispensed with. The predefined period of time is advantageously fixed depending on the form of the electrical energy storage system.

The predefined third degree of diagnostic coverage is expediently defined in dependence on a period of time that has elapsed since the execution or end of the step of performing the at least one predefined diagnosis. This is advantageous since the probability that a change in the electrical energy storage system that is relevant to the diagnosis has occurred generally increases with the time elapsed. It is therefore useful and advantageous to require, for a relatively long period of time, a relatively high degree of diagnostic coverage that results in more extensive diagnosis. For example, the requirement in most countries is for a degree of diagnostic coverage of at least 33% to be attained, i.e. three restarts of the energy storage system require a diagnosis to be performed at least once. It is therefore conceivable, for example, that a diagnosis of the circuit for current measurement is performed for every second restart, and a corresponding diagnosis of the temperature measurement every third time, since the temperature measurement is cheaper and takes place multiple times and the probability of sensor failure is generally lower.

The fourth to sixth steps are expediently only performed if the electrical energy storage system has previously functioned without faults that can be diagnosed according to the first step. This is advantageous since it ensures that the reliability of the electrical energy storage system is guaranteed, even when diagnoses are performed to a reduced extent. By way of example, the electrical energy storage system is started and the first three steps are performed, i.e. all the relevant diagnoses are made. The energy storage system then runs without faults. It is now switched off and switched on again a short time later. The permissible period of time for the time between switching off and switching on can be defined at 1 s, in particular at 300 ms to 500 ms, for example. The system was therefore running without faults shortly before being switched off and switched on again. The aforementioned condition is therefore fulfilled and diagnoses can be omitted to make the electrical energy storage system available more rapidly.

The at least one predefined diagnosis expediently comprises a diagnosis of a temperature of the electrical energy storage system and/or a diagnosis of a voltage of the electrical energy storage system and/or a diagnosis of an electrical current of the electrical energy storage system. This is advantageous since these diagnoses ensure that the electrical energy storage system is functioning reliably and safely.

The diagnosis of a temperature of the electrical energy storage system expediently comprises plausibilization of a measured temperature and/or a diagnosis of the temperature measurement chain. This is advantageous since it means that both measurement values and sensors are covered by the diagnosis and faults can be detected in each case.

The diagnosis of a voltage of the electrical energy storage system expediently comprises plausibilization of a measured voltage and/or a diagnosis of the voltage measurement chain. This is advantageous since it means that both measurement values and sensors are covered by the diagnosis and faults can be detected in each case.

The diagnosis of an electrical current of the electrical energy storage system expediently comprises plausibilization of a measured electrical current and/or a diagnosis of the current measurement chain. This is advantageous since it means that both measurement values and sensors are covered by the diagnosis and faults can be detected in each case.

The degree of diagnostic coverage is expediently defined as an IUMPR quota. This is advantageous since certain quotas, which can differ depending on the country, are prescribed for this purpose. The respective diagnostic requirements can therefore always be met.

The IUMPR quota is preferably greater than or equal to 33%.

The disclosure furthermore relates to an apparatus for operating an electrical energy storage system, comprising at least one means, in particular an electronic battery management control device, that is configured to execute the steps mentioned above. The advantages mentioned above can be achieved as a result. A battery management control device can in particular be understood to mean an electronic control unit in the form of an electronic control device that comprises a microcontroller and/or an application-specific hardware module, e.g., an ASIC, for example, but equally it can include a programmable logic controller.

The invention furthermore relates to an electrical energy storage system that comprises the apparatus mentioned above. The advantages mentioned above can be achieved as a result.

### BRIEF DESCRIPTION OF THE DRAWINGS

Advantageous embodiments of the invention are illustrated in the figures and explained in more detail in the description below.

In the figures:

FIG. 1 shows a flow diagram of the disclosed method according to a first embodiment;

FIG. 2 shows a flow diagram of the disclosed method according to a second embodiment;

FIG. 3 shows a flow diagram of the disclosed method according to a third embodiment;

FIG. 4 shows a schematic illustration of the disclosed apparatus according to a first embodiment.

Identical reference signs denote identical apparatus components or identical method steps in all the figures.

### DETAILED DESCRIPTION

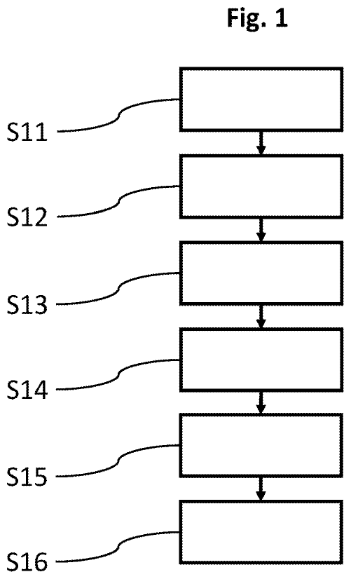

FIG. 1 shows a flow diagram of the disclosed method according to a first embodiment. At least one predefined diagnosis of the electrical energy storage system is performed in a first step S11, wherein the at least one predefined diagnosis attains at least a predefined first value for the degree of diagnostic coverage.

An obtained second value for the degree of diagnostic coverage is determined in a second step S12, which value depends on the at least one predefined diagnosis performed in the first step S11. It is therefore also possible for this value to be greater than the predefined first value, which is to be understood as a minimum value.

The obtained second value for the degree of diagnostic coverage is stored in a first data memory in a third step S13 to make it possible to retrieve it during what is known as an onboard diagnosis, for example.

Subsequently, a portion of the at least one diagnosis performed in the first step S11 is performed in a fourth step S14 to obtain a predefined third value for the degree of diagnostic coverage. Therefore, not all of the diagnosis performed in the first step S11 is performed, at least the predefined third value for the degree of diagnostic coverage that is acceptable for the instance of application being attained nevertheless.

An obtained fourth value for the degree of diagnostic coverage is determined in a fifth step S15, which value is dependent on the portion of the at least one diagnosis that was performed in the fourth step S14. It is therefore also possible for this value to be greater than the predefined third value, which is to be understood as a minimum value.

The obtained fourth value for the degree of diagnostic coverage is stored in a second data memory in a sixth step S16 to make it possible to read it during what is known as an onboard diagnosis, for example.

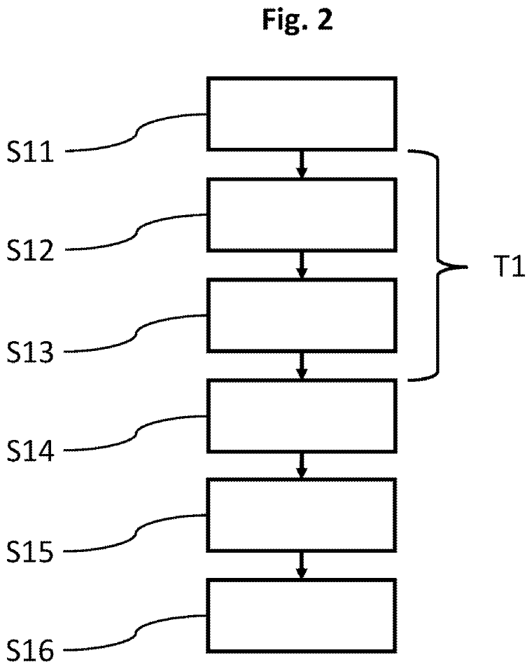

FIG. 2 shows a flow diagram of the disclosed method according to a second embodiment.

Steps S11 to S16 are also explained here, wherein the fourth step S14 is started within a predefined period of time T1 from the end of the first step S11. In this case, the predefined period of time T1 is fixed in a manner specific to the application. For example, it can be in the range from 0 s to 60 s in the case of a battery system as electrical energy storage system that comprises a plurality of battery cells. In addition, before the fourth step S14, a check can be performed to determine whether, for example, a predefined condition has been fulfilled within the predefined period of time T1. For example, this condition can be that an ignition has been actuated to start a vehicle in which the electrical energy storage system is installed. Actuation of the ignition may have first taken place even before the first step S11, and so a further actuation is then checked before the fourth step S14, for example. This is advantageous to allow more rapid retrieval of electrical energy if the vehicle has been switched off again via the ignition in the meantime.

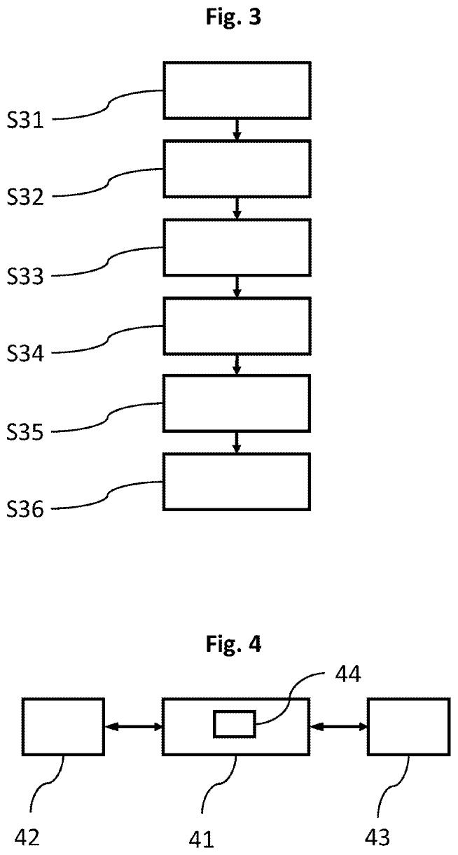

FIG. 3 shows a flow diagram of the disclosed method according to a third embodiment. Diagnoses relating to a temperature, a voltage and an electrical current are performed in a first step S31. To this end, a temperature of the electrical energy storage system is acquired and plausibilized, for example by means of an acquisition by a plurality of temperature sensors. Furthermore, a diagnosis of the temperature measurement chain is performed, which can comprise self-diagnosis of the temperature sensors, for example, to diagnose faulty acquisition or distortion of temperature measurement values.

Furthermore, a voltage of the electrical energy storage system is acquired and plausibilized, for example by means of an acquisition by a plurality of voltage sensors and/or by means of a comparison of a usual voltage range of the electrical energy storage system. If the acquired voltage is consequently outside of this usual voltage range, which, for example, is in the range between 2.5 V and 4.2 V for battery cells, then there is an anomaly and operation of the electrical energy storage system is at least restricted or completely prevented, if appropriate. Furthermore, a diagnosis of the voltage measurement chain is performed, which can comprise self-diagnosis of the voltage sensors, for example, to diagnose faulty acquisition or distortion of voltage measurement values.

Furthermore, an electrical current of the electrical energy storage system is acquired and plausibilized, for example by means of an acquisition by a plurality of current sensors and/or by means of a comparison of a usual current range of the electrical energy storage system. If the acquired current is consequently outside of this usual current range, which, for example, in terms of absolute value is in the range from 0 A to 200 A for battery cells, in particular in the range from 0 A to 10 A, if no electrical energy is retrieved for propulsion of a vehicle, then there is an anomaly and operation of the electrical energy storage system is at least restricted or completely prevented, if appropriate. Furthermore, a diagnosis of the current measurement chain is performed, which can comprise self-diagnosis of the current sensors, for example, to diagnose faulty acquisition or distortion of current measurement values.

These diagnoses obtain at least a predefined first value for the degree of diagnostic coverage.

The first step S31 can be preceded by a triggering fulfillment of a condition, for example switching-on of the ignition of a vehicle, wherein this then triggers the first step S31. This switching-on can also correspondingly come first in each of the other embodiments described here.

The second value for the degree of diagnostic coverage that is obtained by the diagnoses performed in the first step S31 is determined in a second step S32. The second value in this case is greater than or equal to the first value required in the first step S31.

The second value thus obtained for the degree of diagnostic coverage is stored in a first data memory in a third step S33.

Only a portion of the diagnoses described for the first step S31 is carried out in a fourth step S34, in this case the diagnosis of the temperature and the voltage as described above, wherein these diagnoses obtain at least a predefined third value for the degree of diagnostic coverage.

The fourth step S34 can be preceded by a triggering fulfillment of a condition, for example switching-on of the ignition of the vehicle again, wherein this then triggers the fourth step S34. This further switching-on can also correspondingly come first in each of the other embodiments described here.

A fourth value for the degree of diagnostic coverage that is obtained by the diagnoses in the fourth step S34 is determined in a fifth step S35. The fourth value in this case is greater than or equal to the third value required in the fourth step S34.

The second value thus obtained for the degree of diagnostic coverage is stored in a second data memory in a sixth step S36.

FIG. 4 shows a schematic illustration of the disclosed apparatus 41 according to a first embodiment. The apparatus 41 comprises a means 44 that is configured to carry out the disclosed method. In this case, one or more appropriate sensors 42 acquire applicable measurement values for voltage, current and temperature, for example, and transfer them to the apparatus 41, where they are evaluated, and, if appropriate, used in the diagnoses, by the means 44. The apparatus 41 then actuates a power electronics component 43, for example an inverter, on the basis of the diagnostic result or results.

1. A method for the rapid initialization of an electrical energy storage system, the method comprising the steps:
a) performing at least one predefined diagnosis of the electrical energy storage system to obtain at least a predefined first degree of diagnostic coverage;
b) determining an obtained second degree of diagnostic coverage on the basis of the at least one diagnosis performed in step a);
c) storing the obtained second degree of diagnostic coverage in a first data memory;
d) performing no more than a portion of the at least one predefined diagnosis from step a) to obtain at least a predefined third degree of diagnostic coverage;
e) determining an obtained fourth degree of diagnostic coverage on the basis of the portion of the at least one predefined diagnosis that was performed in step d);
f) storing the obtained fourth degree of diagnostic coverage in a second data memory.

2. The method as claimed in claim 1, wherein the electrical energy storage system comprises a plurality of electrical energy storage units.

3. The method as claimed in claim 1, wherein step d) is started within a predefined period of time, in particular within 60 s, from the execution or end of step a).

4. The method as claimed in claim 1, wherein the predefined third degree of diagnostic coverage is defined in dependence on a period of time that has elapsed since step a).

5. The method as claimed in claim 1, wherein steps d) to e) are only performed if the electrical energy storage system has previously functioned without faults that can be diagnosed according to step a).

6. The method as claimed in claim 1, wherein the at least one predefined diagnosis comprises a diagnosis of a temperature of the electrical energy storage system and/or a diagnosis of a voltage of the electrical energy storage system and/or a diagnosis of an electrical current of the electrical energy storage system.

7. The method as claimed in claim 6, wherein the diagnosis of a temperature of the electrical energy storage system comprises plausibilization of a measured temperature and/or a diagnosis of the temperature measurement chain.

8. The method as claimed in claim 6, wherein the diagnosis of a voltage of the electrical energy storage system comprises plausibilization of a measured voltage and/or a diagnosis of the voltage measurement chain.

9. The method as claimed in claim 6, wherein the diagnosis of an electrical current of the electrical energy storage system comprises plausibilization of a measured electrical current and/or a diagnosis of the current measurement chain.

10. The method as claimed in claim 1, wherein the degree of diagnostic coverage is defined as an IUMPR quota.

11. An apparatus for operating an electrical energy storage system, comprising at an electronic battery management control device, that is configured to
a) perform at least one predefined diagnosis of the electrical energy storage system to obtain at least a predefined first degree of diagnostic coverage;
b) determine an obtained second degree of diagnostic coverage on the basis of the at least one diagnosis performed in step a);
c) store the obtained second degree of diagnostic coverage in a first data memory;
d) perform no more than a portion of the at least one predefined diagnosis from step a) to obtain at least a predefined third degree of diagnostic coverage;
e) determine an obtained fourth degree of diagnostic coverage on the basis of the portion of the at least one predefined diagnosis that was performed in step d);
f) store the obtained fourth degree of diagnostic coverage in a second data memory.

12. (canceled)
